(19) United States
(12) Patent Application Publication
(10) Pub. No.: US 2006/0150914 A1
(43) Pub. Date: Jul. 13, 2006

(54) Plasma process device

(76) Inventors: Naoko Yamamoto, Osaka-shi (JP); Tatsushi Yamamoto, Ikoma-gun (JP); Masaki Hirayama, Sendai-shi (JP); Tadahiro Ohmi, Sendai-shi (JP)

Correspondence Address: EDWARDS & ANGELL, LLP, P.O. BOX 55874, BOSTON, MA, 02205, US

(21) Appl. No.: 10/545,355

(22) PCT Filed: Feb. 20, 2004
(86) PCT No.: PCT/JP04/02043

§ 371 Date: Aug. 11, 2005

(30) Foreign Application Priority Data
Feb. 25, 2003 (JP) 2003-047695

(51) Int. Cl. C23C 16/00; C23F 1/00

(52) U.S. Cl. 118/723 MW; 156/345.41

(57) ABSTRACT

A plasma processing apparatus includes: a processing chamber; an inlet waveguide having an interior space in which a first standing wave of a microwave is formed by means of resonance; a dielectric within which a second standing wave of the microwave is formed by means of resonance; and a slot antenna having a slot through which the microwave is passed from the interior space to the dielectric. The slot is generally located at a point where the position of a loop in the first standing wave orthogonally projected to the slot antenna coincides with the position of a loop in the second standing wave orthogonally projected to the slot antenna. The present invention provides a plasma processing apparatus that improves the propagation efficiency of a microwave passed through an aperture of the slot antenna, thereby allowing microwave energy to be efficiently introduced into a processing chamber.

### TECHNICAL FIELD

The present invention is related generally to a plasma processing apparatus, and more particularly, to a plasma processing apparatus such as dry etching equipment, deposition equipment and ashing systems used in manufacturing processes of semiconductors, liquid crystal display devices and solar cells, for example.

In recent years, plasma processing equipment has been developed to process a substrate with a greater surface area to cope with increasingly greater substrate surfaces used in the manufacturing of semiconductors or flat panel displays (FPDs) such as liquid crystal displays (LCDs). Particularly, FPD manufacturing equipment is being developed targeted for substrates with a side of one meter or greater. When a plasma processing apparatus performs microtreatments and deposition on such large substrates, how to create a uniform plasma and to ensure consistent processes such as various treatments and deposition is a major concern.

In terms of uniformity of a plasma and consistency in processing as well as their control, plasma processing equipment using inductive coupling or a power supply at frequencies in the microwave range (frequencies ranging from 100 MHz to 10 GHz) achieves better results than that using capacitive coupling which was mainly employed, since the former type is configured such that the power for the plasma source can be controlled independently from the power for biasing the substrate. This facilitates process control, resulting in increasingly wide use of this type.

A plasma processing apparatus using a power source at frequencies in the microwave range is typically configured to introduce microwave energy directed by a waveguide or a coaxial cable into the processing chamber through a dielectric that serves as a slot antenna as well as a vacuum seal.

In a plasma processing apparatus for larger substrates, a plurality of slots are typically provided in the slot antenna. The position of the center of each of the slots and the distance between them are critical in whether microwave energy from the source can be efficiently introduced into the processing chamber.

Prior documents disclosing the positioning of slots include Japanese Patent Laying-Open Nos. 11-121196 and 10-241892. FIG. 8 is a cross sectional view of a microwave plasma processing apparatus disclosed in Japanese Patent Laying-Open No. 11-121196.

Referring to FIG. 8, on top of a reactor 101 that defines a processing chamber 102 therewithin, a sealing plate 104 is provided, which is formed by a dielectric. The upper surface of sealing plate 104 is covered with a cover member 110. A waveguide type antenna 112 is provided on top of cover member 110 to introduce a microwave into processing chamber 102. Waveguide type antenna 112 is connected via a waveguide 121 to a microwave oscillator 120 that provides an oscillating microwave. One end of waveguide type antenna 112 which is linear-shaped is connected with waveguide 121. The other, arced, end of waveguide type antenna 112 forms a closed end above reactor 101. A plurality of slits 115 are provided in the portion of cover member 110 that are below waveguide type antenna 112.

An oscillating microwave generated by microwave oscillator 120 is superimposed within waveguide type antenna 112 on a wave reflected from the end of antenna 112. This results in a standing wave within antenna 112. Each slit 115 is provided at n·λg/2 (n is a natural number and λg is the wavelength of the microwave) from the end of waveguide type antenna 112.

FIG. 9 is a cross sectional view of a plasma processing apparatus disclosed in Japanese Patent Laying-Open No. 10-241892. Referring to FIG. 9, a plasma processing apparatus 220 includes a processing chamber 222 defined by a chamber body 221, and a plasma generating space 226 above processing chamber 222. An oscillator 229 is provided spaced apart from chamber body 221 for generating a microwave. A waveguide 230 is provided above plasma generating space 226. One end of waveguide 230 is connected with oscillator 229 and the other end of waveguide 230 has a short-circuit surface 230a that reflects a microwave. A top plate 231 having a slot antenna formed therein, not shown, is provided close to the other end of waveguide 230. A microwave transmissive window 233, formed by a dielectric, is provided below top plate 231. Microwave transmissive window 233 is attached to an attachment 234 on the wall that defines plasma generating space 226.

Microwave transmissive window 233 forms a composite wave from an incident microwave advancing toward an attachment 234 and a reflected microwave reflected from this attachment 234. The width W of microwave transmissive window 233 is determined to satisfy W=λsw/2×n (λsw is the wavelength of the microwave, and n is an integer). A slot antenna is provided at λsw/2 away from the end of microwave transmissive window 233.

A microwave plasma processing apparatus disclosed in Japanese Patent Laying-Open No. 11-121196 directs a microwave from microwave oscillator 120 in the direction of processing chamber 102 through waveguide type antenna 112. The microwave that has reached sealing plate 104 through slit 115 is then directed toward processing chamber 102. Unfortunately, slits 115 are only positioned based on the wavelength of the microwave propagating through waveguide type antenna 112, and sealing plate 104 is thus not taken into consideration, such that some configurations of sealing plate 104 and some relative dielectric constants of the dielectric forming sealing plate 104 may prevent a microwave from being efficiently introduced into processing chamber 102.

A plasma processing apparatus 220 disclosed in Japanese Patent Laying-Open No. 10-241892 directs a microwave from oscillator 229 in the direction of plasma generating space 226 through waveguide 230. The microwave that has reached microwave transmissive window 233 through the slot antenna is then introduced into plasma generating space 226. Unfortunately, the slot antenna is positioned without taking e.g. the configuration of waveguide 230 into consideration, such that some configurations of waveguide 230 may prevent a microwave from being efficiently introduced into plasma generating space 226. Moreover, positioning the slot antenna away from the end of microwave transmissive window 233 at a distance of λsw/2 is inappropriate for efficiently introducing a microwave.

An object of the present invention is to solve the above problems by providing a plasma processing apparatus that provides improved propagation efficiency of a microwave passed through an aperture in a slot antenna to allow microwave energy to be efficiently introduced into a processing chamber.

### DISCLOSURE OF THE INVENTION

A plasma processing apparatus according to the present invention includes: a processing chamber for performing plasma-assisted processing; microwave introducing means having an interior space in which a first standing wave of a microwave is formed by means of resonance, the microwave introducing means directing the microwave to the processing chamber; a dielectric provided between the processing chamber and the microwave introducing means and adjacent the interior space for directing the microwave into the processing chamber, a second standing wave of the microwave being formed within the dielectric by means of resonance; and a slot antenna covering a side of the dielectric that faces the interior space. The slot antenna has an aperture-through which the microwave is passed from the interior space to the dielectric. The aperture is generally located at a point where the position of a loop in the first standing wave orthogonally projected to the slot antenna coincides with the position of a loop in the second standing wave orthogonally projected to the slot antenna.

A plasma processing apparatus constructed as described above has an aperture in the slot antenna at a position corresponding to loops in the first and second standing waves. A loop in a standing wave means the portion of a microwave at which its electric field strength is at its maximum, and a node in a standing wave means the portion of a microwave at which its electric field strength is at its minimum. Loops and nodes in a standing wave appear alternately at a certain distance (¼ of the wavelength of the microwave). Accordingly, a microwave can be propagated from the interior space to the dielectric through the aperture with its direction kept constant. As a result, the propagation efficiency of a microwave can be improved and microwave energy can be efficiently introduced into the processing chamber.

Preferably, a plurality of apertures are provided at a distance d. When the wavelength of the microwave in the interior space in which the first standing wave is formed is represented by λp and the wavelength of the microwave within the dielectric in which the second standing wave is formed is represented by λq, the distance d between the apertures satisfies d=m·λp/2 (m is a natural number) and d=n·λq/2 (n is a natural number). A plasma processing apparatus constructed as described above provides loops in the first and second standing waves appearing at λp/2 and λq/2, respectively. Accordingly, natural numbers m and n that satisfy m·λp/2=n·λq/2 are calculated and, from these m and n, the distance d is determined at which apertures are to be provided. Apertures can then be provided at the distance d such that the apertures are located at positions corresponding to loops in the standing waves.

Preferably, the first and second standing waves have electric fields substantially in one and the same direction at those loops in the first and second standing waves which are projected to one and the same aperture. A plasma processing apparatus constructed as described above can reduce the variation in the orientation of an electric field for any of the plurality of apertures, thereby minimizing reflected wave. Thus, microwave energy can be introduced into the processing chamber still more efficiently.

### BRIEF DESCRIPTION OF THE DRAWINGS

FIG. 1 is a cross sectional view of a plasma processing apparatus in a first embodiment of the present invention.

FIG. 2 is a cross sectional view of the apparatus along the line II-II in FIG. 1.

FIG. 3 is a cross sectional view of the apparatus illustrating the electric field strength of standing waves formed in the interior space and dielectrics using a simulation in the first embodiment.

FIG. 4 is a schematic view illustrating the positions of standing waves formed in the interior space and dielectrics relative to slots in another simulation for comparison.

FIG. 5 is another schematic view illustrating the positions of standing waves formed in the interior space and dielectrics relative to slots in yet another simulation for comparison.

FIG. 6 is yet another schematic view illustrating the positions of standing waves formed in the interior space and dielectrics relative to slots in still another simulation for comparison.

FIG. 7 is a cross sectional view of an apparatus illustrating the electric field strength of standing waves formed in the interior space and dielectrics using a simulation in a second embodiment.

FIG. 8 is a cross sectional view of a microwave plasma processing apparatus disclosed in Japanese Patent Laying-Open No. 11-121196.

FIG. 9 is a cross sectional view of a plasma processing apparatus disclosed in Japanese Patent Laying-Open No. 10-241892.

### BEST MODES FOR CARRYING OUT THE INVENTION

Embodiments of the present invention will now be described with reference to the drawings.

### First Embodiment

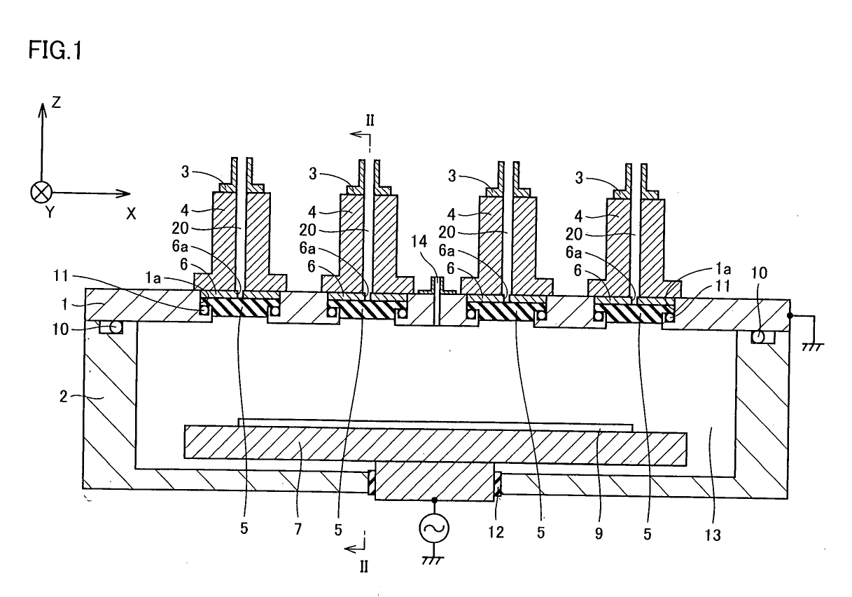

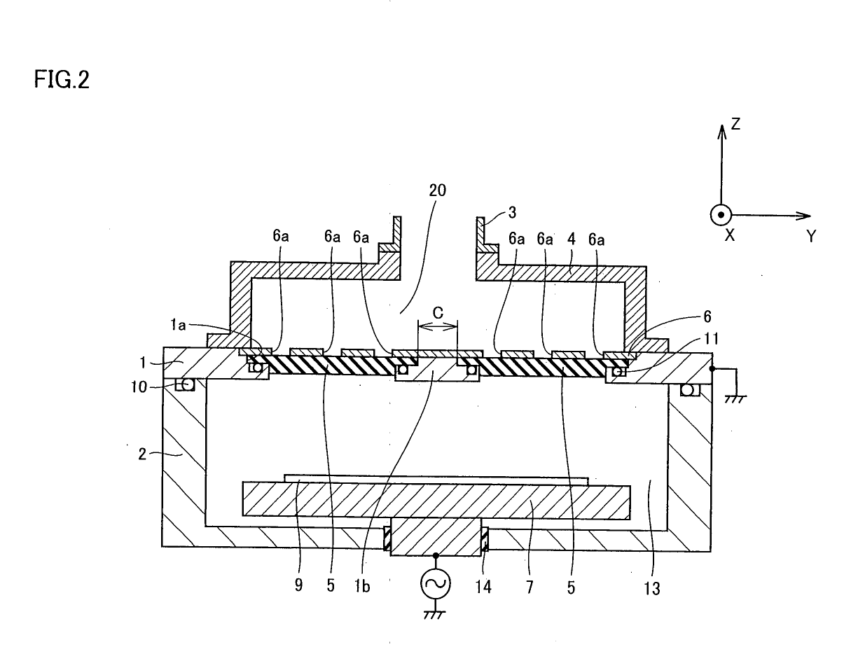

In the present embodiment, the structure of a plasma processing apparatus will be described below, where the plane along which the paper surface of FIG. 1 extends is defined as the X-Z plane while the plane along which the paper surface of FIG. 2 extends is defined as the Y-Z plane.

Referring to FIGS. 1 and 2, a plasma processing apparatus includes a processing chamber body 2 that has an aperture on its top surface and defines a processing chamber 13 therewithin, a chamber lid 1 provided on top of processing chamber body 2, a dielectric 5 provided in chamber lid 1, a slot antenna 6, and an inlet waveguide 4.

Within processing chamber 13, a substrate holder 7 is attached to processing chamber body 2 with an interposed insulator 12. A substrate 9, on which plasma processing in processing chamber 13 is performed, is placed on the top surface of substrate holder 7. A gasket 10 is provided at the contact between chamber lid 1 and processing chamber body 2 to ensure the sealing. Processing chamber 13 is connected to a vacuum pump, not shown.

Chamber lid 1 has a plurality of rectangular apertures 1a spaced apart from each other at a certain distance. Four apertures 1a form a row along the X direction, while two form a column along the Y direction. Each aperture 1a has a dielectric plate 5 fitted therein via a gasket 11 for sealing. Dielectric 5 is formed of alumina (Al₂O₃).

Dielectric 5 serves to vacuum seal processing chamber 13 as well as to propagate a microwave therethrough. A vacuum pump, not shown, may be operated to keep processing chamber 13 evacuated at around 10⁻⁴ Pa to 10⁻⁵ Pa. A gas introducing conduit 14 is provided in chamber lid 1 to introduce a process gas into processing chamber 13.

Although not shown, a temperature regulator is provided at chamber lid 1, processing chamber body 2 and substrate holder 7 in order to keep a constant temperature.

A slot antenna 6 is provided on the top surface of dielectric 5, i.e. opposite the side facing processing chamber 13. Slot antenna 6 extends to cover the entire top surface of dielectric 5. A slot antenna 6 has a plurality of slots 6a arranged along the Y direction.

Inlet waveguide 4 is provided on slot antenna 6. Inlet waveguide 4 defines an interior space 20 adjacent slot 6a formed in slot antenna 6. Interior space 20 has a size in the Y direction that is longer than that in the X direction. Atop inlet waveguide 4 is provided a waveguide 3 communicating with interior space 20. Waveguide 3 is connected with a magnetron, not shown, via a microwave circuit, also not shown. The microwave circuit is composed of an isolator, an automatic matching device, and a Japanese Industrial Standard (JIS) compatible straight waveguide, corner waveguide, taper waveguide and branch waveguide and the like.

The further description below assumes that the plasma processing apparatus shown in FIGS. 1 and 2 are used for dry etching equipment.

A microwave generated from a magnetron, not shown, at a frequency of 2.45 GHz, for example, is passed through a microwave circuit, not shown, to reach waveguide 3. The microwave further advances through waveguide 3 to interior space 20 and propagates through a slot 6a in slot antenna 6 to dielectric 5. The microwave is then directed through dielectric 5 to processing chamber 13.

The microwave directed to processing chamber 13 energizes a process gas composed of, for example, CF₄, Cl₂, O₂, N₂ or Ar or a gaseous mixture thereof, introduced through gas introducing conduit 14. As a result, the process gas becomes a plasma (ionized gas). The plasma is utilized to etch substrate 9 placed on substrate holder 7 (for example, a glass substrate on which a single layer or a stack made of a metal such as Al or an insulator is deposited with a resist placed thereon used in forming interconnects or contact holes).

Rendering a process gas into a plasma generally requires more energy for greater surface area of the work piece i.e. a substrate. Accordingly, processing a substrate with a large surface area, such as with a side greater than one meter, requires a total supply output of a plasma processing apparatus of several kW to tens of kW. Thus, it is crucial to be able to introduce microwave energy into processing chamber 13 as efficiently as possible.

In particular, suppose that a microwave at high frequencies, for example 2.45 GHz is introduced; then, the wavelength of the microwave in a free space will be 122 mm. Thus, the wavelength of the microwave is shorter than the substrate size. Consequently, when a microwave with frequencies on the order of GHz is used, the size of the waveguide, the position of the slots and the distance between them, the relative dielectric constant and the size of the dielectric and the like are critical in appropriately controlling propagation properties of the microwave and the consistency in processing.

In other words, inlet waveguide 4 and dielectric 5 through which a microwave is passed before being introduced into processing chamber 13 serve as a resonator to form a standing wave of the microwave within interior space 20 and dielectric 5. For a microwave with a wavelength λ, a node, at which the electric field strength is at its minimum, appears at every λ/2 in a standing wave, and a loop, at which the electric field strength is at its maximum, appears at every λ/2 separated from a node by λ/4. The ends of interior space 20 and the ends of dielectric 5 provide fixed ends of an electric field and thus always correspond to nodes in a standing wave.

The configuration of inlet waveguide 4 and dielectric 5, as well as the relative dielectric constant of dielectric 5 are such that the position of a loop in a standing wave in interior space 20 orthogonally projected to slot antenna 6 may coincide with the position of a loop in a standing wave in dielectric 5 orthogonally projected to slot antenna 6, where the positions of the loops in the standing waves in interior space 20 and in dielectric 5 can be determined by a computer simulation using the configurations of inlet waveguide 4 and dielectric 5 as well as the relative dielectric constant of dielectric 5 as parameters.

A slot 6a is located at a point where the position of a loop in a standing wave in interior space 20 orthogonally projected to slot antenna 6 coincides with the position of a loop in a standing wave in dielectric 5 orthogonally projected to slot antenna 6. In other words, each slot 6a is formed on slot antenna 6 directly below a loop in a standing wave in interior space 20 and directly above a loop in a standing wave in dielectric 5.

For such positioning of slots 6a, since a standing wave of a microwave has a loop at every λ/2, the distance d between slots 6a can be represented as: d=m·p/2=n·λq/2 (in and n are arbitrary natural numbers satisfying the above equation, λp is the wavelength of a microwave formed in interior space 20, and λq is the wavelength of a microwave formed in dielectric 5).

A plasma processing apparatus according to the first embodiment of the present invention includes: a processing chamber 13 for performing plasma-assisted processing; an inlet waveguide 4 as microwave introducing means which has an interior space 20 in which a first standing wave of a microwave is formed by means of resonance, the waveguide directing the microwave toward processing chamber 13; a dielectric 5 provided between processing chamber 13 and inlet waveguide 4 and adjacent interior space 20 to direct the microwave into processing chamber 13, a second standing wave of the microwave being formed within the dielectric by means of resonance; and a slot antenna 6 having a slot 6a that serves as an aperture through which the microwave is passed from interior space 20 into dielectric 5, the antenna covering the side of dielectric 5 facing interior space 20. Slot 6a is generally located at a point where the position of a loop in the first standing wave orthogonally projected to slot antenna 6 coincides with the position of a loop in the second standing wave orthogonally projected to slot antenna 6.

A plurality of slots 6a are provided at the distance d. The distance d satisfies d=n·λp/2 (n is a natural number) and d=m·λq/2 (m is a natural number), where λp is the wavelength of the microwave in interior space 20 in which the first standing wave is formed, and λq is the wavelength of the microwave in dielectric 5 in which the second standing wave is formed.

A plasma processing apparatus thus configured allows microwave energy to be efficiently introduced into the processing chamber. In other words, the magnetic field is relatively strong directly below a loop in a standing wave in interior space 20, such that a slot 6a provided there allows a large current to be induced around slot 6a. This current in turn induces a large magnetic field from slot 6a. Further, a wave such as a microwave typically has higher propagation efficiency when propagated in a straight line. Wave propagation in a curve will result in a reflected wave at the curved point, resulting in lower propagation efficiency. In the present embodiment, slot 6a is located directly above a loop in a standing wave in dielectric 5, such that a microwave can be propagated in a straight line through slot 6a from interior space 20 to dielectric 5. In this way, the energy loss of a microwave during propagation can be minimized. For the above reasons, the propagation efficiency of a microwave can be improved whereby microwave energy can be efficiently introduced into processing chamber 13.

A simulation was conducted on a computer as described below to enable the designing of an actual plasma processing apparatus in the present embodiment.

A microwave generated from a magnetron, not shown, was rendered to that of a single mode TE (1, 0) by means of a JIS waveguide, and the microwave was able to be propagated in a single mode TE (1, 0) through a straight waveguide, corner waveguide, taper waveguide and branch waveguide and the like. The single mode TE (1, 0) was able to be efficiently converted to another mode and the microwave was able to be introduced into processing chamber 13.

Here, s and t in the TE (s, t) mode each indicates a mode of a wave. A transverse electric (TE) wave is a wave in which the direction of an electric field only lies on a plane (e.g. the X-Y plane) perpendicular to the direction in which the electromagnetic wave advances (e.g. the Z direction). s indicates the mode of one direction (e.g. the X direction) component representing the direction of that electric field, while t indicates the mode of a direction (e.g. the Y direction) component perpendicular to the direction indicated by s. The TE (1, 0) mode indicates a fundamental wave that can be propagated by a square (rectangular) waveguide, and greater values for s and t mean a mode of a wave of higher orders (harmonic).

First, an inlet waveguide 4 was designed such that an interior space 20 had dimensions of 16 mm in the X direction, 530 mm in the Y direction, and 100 mm in the Z direction. Thus, inlet waveguide 4 serves as a mode converter that converts a microwave of the TE (1, 0) mode into a microwave of the TE (7, 0) mode.

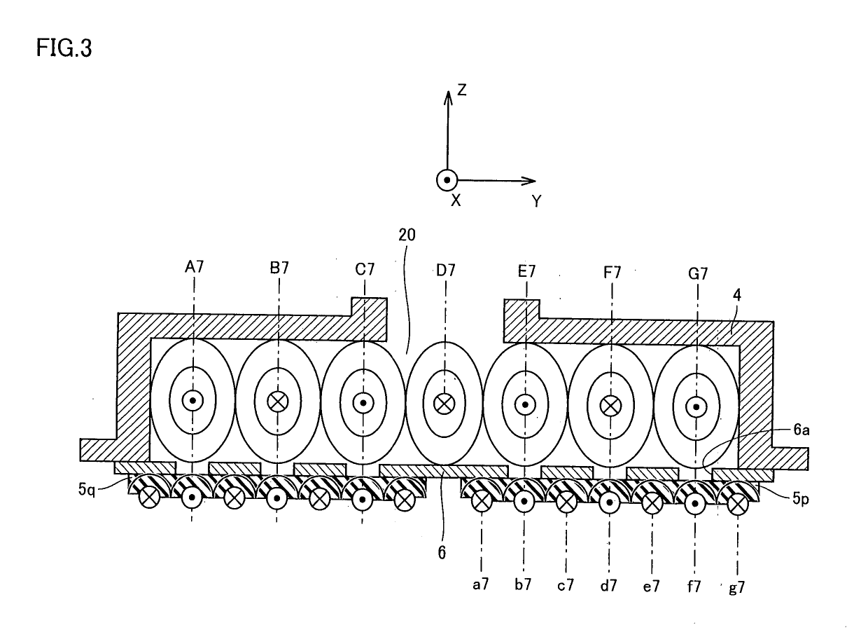

FIG. 3 is an enlarged view of the cross section of interior space 20 and neighboring components shown in FIG. 2, where some details are omitted.

Referring to FIG. 3, an electromagnetic field simulation was conducted to determine the electric field strength distribution of a standing wave of a microwave formed in interior space 20. Near-circles in the figure are contour lines illustrating the electric field strength of a standing wave and indicate stronger field strength toward the center of the near-circles. The symbols in the middle of the near-circles indicate the direction of the electric fields, where a circle with a solid filled center indicates the direction from the paper plane to the viewer, and a circle with a cross in it indicates the direction from the paper plane to the depth

A standing wave of a microwave with a wavelength λp of about 154 mm in the y direction was formed in interior space 20. Thus, loops A7 to G7 in the standing wave were formed at Y coordinates −226 mm, −149 mm, −72 mm, 0, 72 mm 149 mm, and 226 mm, where Y coordinate zero represents the center of inner space 20 in the Y direction. It should be noted that the distance between loops C7 and D7 in the standing wave and the distance between loops D7 and E7 in the standing wave are smaller than the distances between the other adjacent loops in the standing wave, since interior space 20 communicates with waveguide 3 above zero on the Y coordinate axis, which causes a reflected wave at crooked portions of the waveguide, causing distortion in the wave.

Table 1 shows exemplary arrangements of slots 6a with respect to the positions of loops in the standing wave formed in interior space 20.

TABLE 1

| Standing wave in | End | Left | | | | | | | | Right |
|---|---|---|---|---|---|---|---|---|---|---|
| interior space 20 | | end | | | | | | | | end |
| | Loop | | A7 | B7 | C7 | D7 | E7 | F7 | G7 | |
| Y coordinate (mm) | | −265 | −226 | −149 | −72 | 0 | 72 | 149 | 226 | 265 |
| Arrangement | m = 1 | | ◯ | ◯ | ◯ | ◯ | ◯ | ◯ | ◯ | |
| of slots 6a | m = 2 | | ◯ | | ◯ | | ◯ | | ◯ | |
| (◯: slotted) | | | | | | | | | | |
| | | | | ◯ | | ◯ | | ◯ | | |
| | m = 3 | | ◯ | | | ◯ | | | ◯ | |
| | | | | ◯ | | | ◯ | | | |
| | | | | | ◯ | | | ◯ | | |

Referring to Table 1, exemplary arrangements for slots 6a are shown for m=1, 2, 3, where the distance d between adjacent slots 6a is d=m·λp/2. For example, for m=1, a slot 6a can be provided at any of the points on slot antenna 6 onto which the positions of loops A7 to G7 in the standing wave in interior space 20 are orthogonally projected.

Referring to FIG. 3, for the presence simulation, two plates of dielectric 5p and 5q were disposed symmetrically relative to Y coordinate zero, because greater surface area of dielectric 5 impairs the strength of dielectric 5. Dielectrics 5p and Sq were formed of alumina (Al₂O₃) with a relative dielectric constant of about 9. Further, the distance d between slots 6a was d=λp/2, and each of the loops in the standing wave except D7, i.e. A7, B7, C7, E7, F7 and G7 had a slot 6a on slot antenna 6 directly below.

No slot 6a was provided at the position on slot antenna 6 that is directly below loop D7 in the standing wave partly because a waveguide 3 was provided above loop D7 in the standing wave for introducing a microwave into interior space 20. A slot 6a provided at such a position may significantly affect propagation properties of a microwave propagated with a 90° change in its direction of advance in interior space 20. Another reason is that the portion of slot antenna 6 directly below loop D7 in the standing wave was advantageously utilized as a support for separated dielectrics 5p and 5q.

The plasma processing apparatus for the present simulation has a symmetry relative to Y coordinate zero. Accordingly, the description below refers primarily to the region of Y coordinates zero and greater.

Interior space 20 filled with air has a relative dielectric constant of about one. Consequently, wavelength λq of a microwave formed within dielectric 5p is shorter than wavelength λp of a microwave formed in interior space 20. Since wavelength λp of the microwave in interior space 20 is already decided, the positions of loops in the standing waves can easily be matched by multiplying λp by an integer/integer to provide a wavelength λq of a microwave in dielectric 5p. In this example, arrangements were considered for which wavelength λq of a microwave in dielectric 5p was equal to λq multiplied by ½, i.e. 77 mm.

Table 2 shows exemplary trial positions for loops in a standing wave in dielectric 5p with respect to loops D7 to G7 in a standing wave in interior space 20.

TABLE 2

| Standing wave in | Loop | | D7 | | E7 | | F7 | | G7 | |
|---|---|---|---|---|---|---|---|---|---|---|
| interior space 20 | | | | | | | | | | |
| With (◯) or without (X) slot 6a | | | X | | ◯ | | ◯ | | ◯ | |
| Y coordinate (mm) | | | 0 | . . . | 72 | . . . | 149 | . . . | 226 | . . . |
| Trial loop | Trial 1 | TE(5, X) | | | a5 | b5 | c5 | d5 | e5 | |
| positions in | Trial 2-1 | TE(6, X) | | a6 | b6 | c6 | d6 | e6 | f6 | |
| standing wave in | Trial 2-2 | | | | a6′ | b6′ | c6′ | d6′ | e6′ | f6′ |
| dielectric 5p | Trial 3 | TE(7, X) | | a7 | b7 | c7 | d7 | e7 | f7 | g7 |

Table 2 shows the Y coordinates for loops D7 to G7 in the standing wave in interior space 20, whether these positions have a slot 6a or not, and exemplary trial positions for loops in the standing wave in dielectric 5p.

Trial 1 represents a microwave of the TE (5, t) (t is an integer) mode in dielectric 5p, Trials 2-1 and 2-2 each represent a microwave of the TE (6, t) (t is an integer) mode in dielectric 5p, and Trial 3 represents a microwave of the TE (7, t) (t is an integer) mode in dielectric 5p. For example, in Trial 3, loops a7 to g7 are formed in the standing wave in dielectric 5p.

To consistently process substrate 9 placed in processing chamber 13, greater surface area of dielectric 5p is preferable. Consequently, a simulation was conducted for Trial 3 to decide the configuration and relative dielectric constant of dielectric 5p.

Specifically, referring to FIGS. 2 and 3, a beam 1b was provided at Y coordinate zero for supporting dielectrics 5p and 5q separated from each other. The required width C of the side of beam 1b that faces slot antenna 6 was determined to be 10 mm or above to provide sufficient strength. Suppose that loop b7 in the standing wave in dielectric 5 is formed at Y coordinate 72 mm, at which loop E7 is formed in the standing wave in interior space 20, and slot 6a is provided there, i.e. at Y coordinate 72 mm. Then, the distance from that slot 6a to that end of dielectric 5p which faces dielectric 5q is required to be 67 mm or below. The distance between loops b7 to d7 in the standing wave is 77 mm, and thus the maximum size of dielectric 5p in the Y direction is 288 mm.

Further, larger width of dielectric 5p (in the X direction) is desired in order to provide larger surface area of dielectric 5p, although restrictions such as the distance between adjacent dielectrics in the X direction need to be taken into account. Moreover, since processing chamber 13 is at high temperatures under vacuum or at low pressure, dielectric 5p is required to have a certain thickness to prevent dielectric 5p from breaking. In addition, to allow dielectric 5p to be supported at an aperture 1a formed in chamber lid 1, the bottom of dielectric 5p is partially cut. Thus, local wavelength changes of the microwave caused by that configuration also need to be taken into consideration.

In view of the above, an electromagnetic field simulation was conducted with regard to the geometry of dielectric 5p where the standing wave formed in dielectric 5p had modes such as TE (7, 0), TE (7, 1) and TE (7, 2). Here, the configurations of inlet waveguide 4, slot antenna 6, slot 6a and dielectric 5p, as well as the relative dielectric constant of dielectric 5p were input to the computer to provide distributions of the intensity and direction of an electric field of a microwave.

Several electromagnetic field simulations were reviewed and one suitable configuration of dielectric 5p was extracted with dimensions of 283 mm in the Y direction, 80 mm in the X direction, and 15 mm in the Z direction.

Further, another electromagnetic field simulation was conducted with only a change in the position of slots 6a. The results indicated that the mode of the standing wave formed in dielectric 5p was almost independent from the position of slots 6a, and generally remained the TE (7, 1) mode. Moreover, the microwave formed in dielectric 5p had a wavelength of about 77 mm, which indicates that loops in the standing wave formed in interior space 20 appeared at a distance of about 77 mm and loops in the standing wave formed in dielectric 5p appeared at a distance of about 39 mm.

Consequently, the number of slots 6a each provided at a position corresponding to loops in both standing waves in interior space 20 and dielectric 5p can be maximized by providing slots 6a at Y coordinates 72 mm, 149 mm and 226 mm. Accordingly, for the entire slot antenna 6, slots 6a were provided at Y coordinates −226 mm, −149 mm, −72 mm, 72 mm, 149 mm, and 226 mm.

The size of slot 6a in the Y direction affects the amount of radiation of a microwave toward processing chamber 13. Accordingly, a simulation was conducted to decide the size of slot 6a in the Y direction that would result in a substantially uniform amount of radiation of a microwave directed to processing chamber 13 from each of slots 6a.

Electric fields were measured in a plasma processing apparatus having a configuration as provided from the above simulation. The results confirmed the ability to efficiently introduce microwave energy into processing chamber 13.

The wavelength of the microwave in dielectric 5 was about 78 mm and slightly different from the wavelength of a microwave in a dielectric from the simulation. However, when the position of loop F7, for example, in the standing wave in interior space 20 is matched with the position of loop d7 in the standing wave in dielectric 5p, the difference between the positions of the loops in both standing waves is about 1 mm. This value can be considered sufficiently small compared with the wavelength of the microwave. In addition, considering the fact that slots 6a were constructed with a certain dimension (in the Y direction), such a difference can be regarded as not significantly affecting the propagation efficiency of a microwave.

Slots 6a of a predetermined dimension each provided at a position as determined according to the above design guideline enabled microwave energy to be efficiently introduced into processing chamber 13, which helped increase the range of conditions (pressure range, for example) for generating a plasma, thereby enabling the construction of a plasma processing apparatus using still less power for generating a plasma.

It should be noted that the size of inlet waveguide 4 and dielectric 5, as well as the number of slots 6a, for example, are a design choice based on the size of the plasma processing apparatus and are not limited to the values mentioned above. Further, the slots were provided on the E plane (the plane parallel to the electric field in a square waveguide) of inlet waveguide 4, although similar advantages can be achieved by providing slots on the H plane (the plane parallel to the magnetic field in a square waveguide), since there is no change in the wavelength of the microwave in interior space 20.

Further, dielectric 5 may also be formed by other dielectrics such as AlN or SiO₂. By selecting the material of dielectric 5, the relative dielectric constant of dielectric 5 can be changed. Moreover, when dielectric 5 is predominantly composed of alumina as above, the relative dielectric constant of dielectric 5 can be regulated by changing the proportion of alumina therein or the composition of other components. In this way, with the configuration and dimension of dielectric 5 being the same, a dielectric having a specified relative dielectric constant can be selected as the material of dielectric 5 so as to provide a microwave in dielectric 5 at a desired wavelength. Thus, the flexibility in designing a plasma processing apparatus can be improved. Further, by mounting a dielectric at interior space 20, the relative dielectric constant of interior space 20 can be regulated as appropriate, which will further improve the flexibility in designing a plasma processing apparatus.

Although two dielectrics 5 for one interior space 20 were described, any number of dielectrics 5 will allow a plasma processing apparatus to be constructed with improved propagation efficiency of a microwave as far as slots 6a are provided according to the above design guideline.

Further, although in the present embodiment a plasma processing apparatus used as dry etching equipment was described, the present invention, which provides a technique to efficiently direct a microwave into a processing chamber using a slot antenna, can be applied to any equipment that performs plasma processing, such as deposition equipment and ashing systems.

Next, the advantages of the plasma processing apparatus according to the present embodiment were confirmed by other simulations for comparison. The simulations for comparison used different positional relationships between slots 6a and the standing waves formed in interior space 20 and dielectric 5 for comparison of the propagation efficiencies of a microwave for the respective positional relationships.

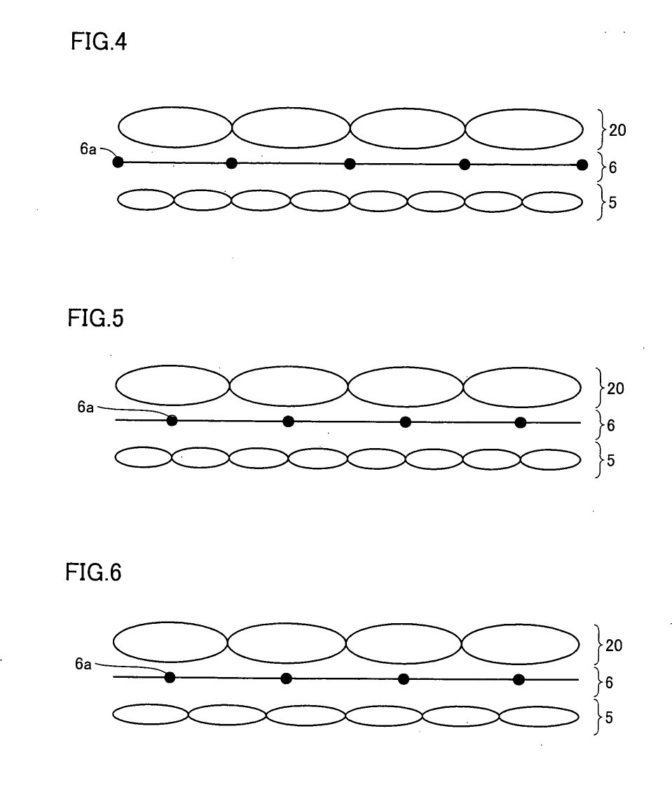

Referring to FIG. 4, each slot 6a was provided at a position where nodes in the standing waves in interior space 20 and dielectric 5 matched up. Here, the microwave had a very low propagation efficiency, presumably because greater part of the energy of the microwave was reflected by slot antenna 6 when coming into slot 6a.

Referring to FIG. 5, each slot 6a was provided at a position for a loop in the standing wave in interior space 20. However, each slot 6a was provided at a position for a node in the standing wave in dielectric 5. In this case, the microwave had a propagation efficiency much lower than that for the simulation according to the present embodiment, but higher than that for the simulation shown in FIG. 4, presumably because microwave energy was efficiently propagated from interior space 20 to slot 6a but major part of the energy of the microwave was reflected when coming into dielectric 5 from slot 6a.

Referring to FIG. 6, each slot 6a was provided at a position for a loop in the standing wave in interior space 20. However, each slot 6a was displaced from positions for loops and nodes in the standing wave in dielectric 5. Here, the microwave had a propagation efficiency much lower than that for the simulation according to the present embodiment, but higher than that for the simulations shown in FIGS. 4 and 5, presumably because microwave energy was reflected when coming into dielectric 5 from slot 6a similar to the case shown in FIG. 5 but in a smaller amount.

### Second Embodiment

A plasma processing apparatus according to a second embodiment is constructed similarly to the plasma processing apparatus in the first embodiment except that the plasma processing apparatus of the second embodiment provides a slot 6a that will result in electric fields in one and the same direction for those loops in standing waves which are formed within interior space 20 and dielectric 5 and are opposite each other with respect to the same slot 6a.

In the plasma processing apparatus according to the second embodiment of the present invention, the electric fields of first and second standing waves have almost the same direction at positions each corresponding to those loops in the first and second standing waves which are projected to the same slot 6a.

A plasma processing apparatus constructed as above can minimize the change in the direction of an electric field for any of the apertures, thereby minimizing reflected wave. Thus, microwave energy can be introduced into processing chamber 13 still more efficiently.

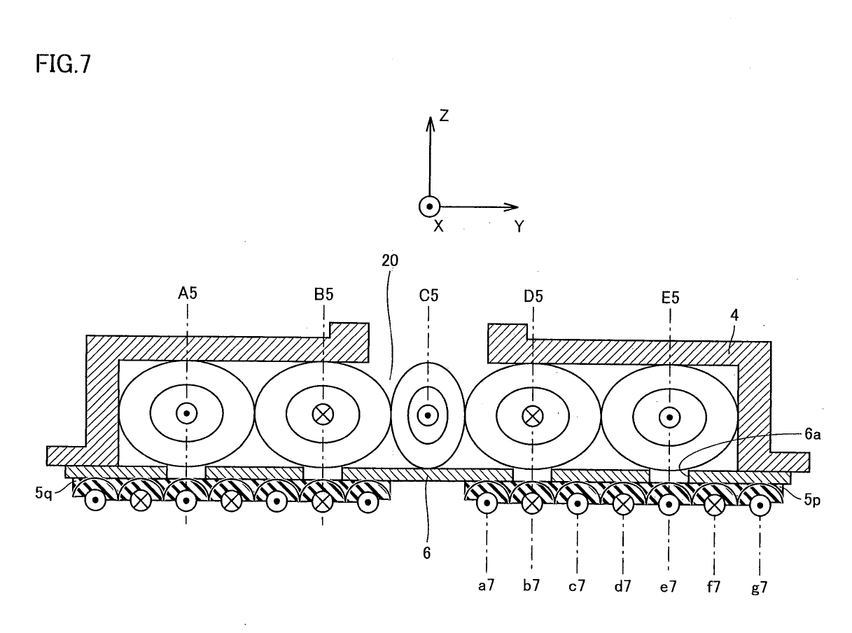

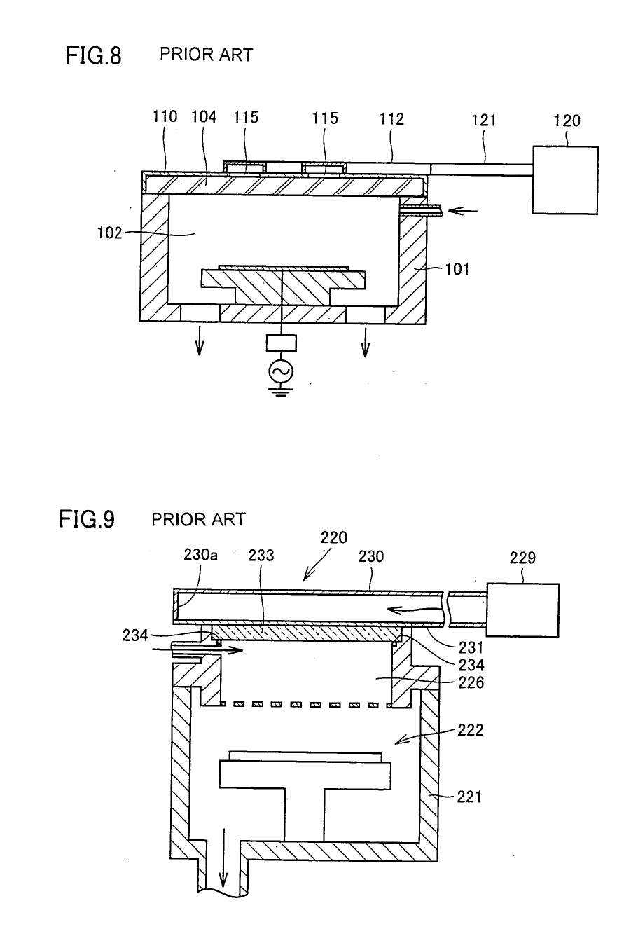

A computer simulation was conducted as below to enable the designing of an actual plasma processing apparatus in the present embodiment. FIG. 7 is a cross sectional view corresponding to FIG. 3 of the first embodiment. It should be noted that the near-circles and the symbols in the middle of the near-circles in FIG. 7 should be interpreted in a similar way to the illustration of FIG. 3 of the first embodiment.

Referring to FIG. 7, an interior space 20 defined by inlet waveguide 4 had dimensions of 16 mm in the X direction, 530 mm in the Y direction and 71.5 mm in the Z direction. Here, the microwave in interior space 20 had a wavelength λp of about 234 mm, and loops A5 to E5 in the standing wave in interior space 20 were formed at a distance of about 117 mm. The major component of the electric fields for loops A5 to E5 in the standing wave had a direction consistent with the X direction and the electric fields for the adjacent loops in the standing wave had opposite directions.

Dielectric 5 was composed of dielectrics 5p and 5q having a configuration as derived from the simulation of the first embodiment. The microwave in dielectric 5p had a wavelength λq of about 77 mm, and loops a7 to g7 in the standing wave in dielectric 5p were formed at a distance of about 39 mm. The positions of loops D5 and E5 in the standing wave in interior space 20 coincided with the positions of loops b7 and e7 in the standing wave in dielectric 5p. The major component of the electric field for loops a7 to g7 for the standing wave in dielectric 5p also had a direction consistent with the X direction, and the electric fields for the adjacent loops in the standing wave had opposite directions.

Consequently, slots 6a were formed directly below loops A5, B5, D5 and E5 in the standing wave in interior space 20 such that the electric fields for opposite loops in the standing waves with respect to one and the same slot 6a had the same direction.

An electric field was measured in a plasma processing apparatus having a configuration as derived from the above simulation. The results confirmed the ability of introducing microwave energy into processing chamber 13 still more efficiently.

It should be noted that the embodiments disclosed herein are by way of example and not limitative in any way. The scope of the present invention is set forth by the claims and not by the above description, and is intended to cover all the modifications within a spirit and scope equivalent to those of the claims.

As described above, the present invention provides a plasma processing apparatus that improves the propagation efficiency of a microwave passed through an aperture of a slot antenna, thereby allowing microwave energy to be efficiently introduced into a processing chamber.

### INDUSTRIAL APPLICABILITY

The present invention is applicable to dry etching equipment, deposition equipment and ashing systems used in manufacturing processes of a liquid crystal display device, solar cell or the like.

1. A plasma processing apparatus comprising:
a processing chamber for performing plasma-assisted processing;
microwave introducing means having an interior space in which a first standing wave of a microwave is formed by means of resonance, the microwave introducing means directing the microwave to said processing chamber;
a dielectric provided between said processing chamber and said microwave introducing means and adjacent said interior space for directing the microwave into said processing chamber, a second standing wave of the microwave being formed within the dielectric by means of resonance; and
a slot antenna having an aperture through which the microwave is passed from said interior space to said dielectric, the slot antenna covering a side of said dielectric that faces said interior space, wherein
said aperture is generally located at a point where the position of a loop in the first standing wave orthogonally projected to said slot antenna coincides with the position of a loop in the second standing wave orthogonally projected to said slot antenna.

2. The plasma processing apparatus according to claim 1, wherein a plurality of apertures are provided at a distance d, the distance d satisfying d=m·λp/2 (m is a natural number) and d=n·λq/2 (n is a natural number), where λp is the wavelength of the microwave in said interior space in which the first standing wave is formed, and λq is the wavelength of the microwave within said dielectric in which the second standing wave is formed.

3. The plasma processing apparatus according to claim 1, wherein the first and second standing waves have electric fields substantially in one and the same direction at those loops in the first and second standing waves which are projected to one and the same aperture.
